(19) United States
(12) Patent Application Publication
(10) Pub. No.: US 2026/0282317 A1
(43) Pub. Date: Sep. 17, 2026

(54) ROTATED 3D DRAM CELL

(71) Applicant: Applied Materials Inc., Santa Clara, CA (US)

(72) Inventors: Fredrick Fishburn, Belmont, CA (US); Raghuveer Satya Makala, Campbell, CA (US); Ruiying Hao, San Jose, CA (US); Zhijun Chen, San Jose, CA (US)

(73) Assignee: Applied Materials Inc., Santa Clara, CA (US)

(21) Appl. No.: 19/081,014

(22) Filed: Mar. 17, 2025

(51) Int. Cl. H10B 12/00

(52) U.S. Cl. CPC H10B 12/02; H10B 12/30

(57) ABSTRACT

Provided are methods of etching a semiconductor substrate. The semiconductor wafer may be intentionally rotated at an angle in a range of from greater than 10 degrees to 45 degrees relative to the <110> crystal direction of the semiconductor wafer prior. An epitaxial stack is formed on the semiconductor wafer, and a slit is etched through the epitaxial film stack to expose a sidewall of the epitaxial film stack. The sidewall of the epitaxial film stack is oriented along a plane of the epitaxial film stack that is aligned from 25 degrees to 45 degrees to the <100> crystal direction.

### TECHNICAL FIELD

Embodiments of the present disclosure pertain to the field of semiconductor devices and semiconductor device manufacturing. More particularly, embodiments of the disclosure provide methods of manufacturing dynamic random-access memory structures with rotated substrates.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bit line, the word line, and the reference voltage. DRAM manufacturing is a highly competitive business. There is continuous pressure to decrease the size of individual cells and to increase memory cell density to allow more memory to be squeezed onto a single memory chip, especially for densities greater than 256 Megabits. Limitations on cell size reduction include the passage of both active and passive word lines through the cell, the size of the cell capacitor, and the compatibility of array devices with nonarray devices.

To scale the density of the 3D DRAM beyond the 10 nm node, the number of stacks of silicon channel and sacrificial layers needs to be increased to more than 100, which can result in 400 epitaxial layers. 3D DRAM relies on selective removal of sacrificial layers, e.g., silicon germanium (SiGe), by selective etching, such as a selective removal process (SRP). To obtain more memory layers vertically, the etching of the sacrificial layers needs to be done with high selectivity and good throughput, while keeping the content of germanium (Ge) in the overall stack relatively low to control wafer stress and relaxation or defect generation in the crystal stack.

Accordingly, there is a need for methods of forming 3D DRAM devices with decreased stress and/or improved etch selectivity.

### SUMMARY

One or more embodiments of the disclosure are directed to methods of etching a semiconductor structure. In one or more embodiments, a method of etching a semiconductor structure comprises: etching a slit through an epitaxial film stack formed on a semiconductor wafer to expose a sidewall of the epitaxial film stack, the sidewall oriented along a plane of the epitaxial film stack that is aligned from 0 degrees to 35 degrees to a <100> crystal direction.

Additional embodiments of the disclosure are directed to methods of etching a semiconductor structure. In one or more embodiments, a method of etching a semiconductor structure comprises: forming an epitaxial film stack on the semiconductor wafer; and etching a slit through the epitaxial film stack to expose a sidewall of the epitaxial film stack, the sidewall oriented along a plane of the epitaxial film stack that is aligned from 25 degrees to 45 degrees to a <100> crystal direction.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments, as described herein, are illustrated by way of example and not limited in the figures of the accompanying drawings in which like references indicate similar elements.

FIG. 1A is a schematic illustrating a plane formed along the <110> crystal direction according to the prior art;

FIG. 1B is a schematic illustrating a plane formed along the <110> crystal direction according to the prior art;

FIG. 1C is a schematic illustrating the location of the face of a DRAM slit wall along the <110> crystal direction according to the prior art;

FIG. 1D is a schematic illustrating a semiconductor wafer having a notch aligned with the <110> crystal direction according to the prior art;

FIG. 2A is a schematic illustrating a plane formed along the <100> crystal direction according to one or more embodiments of the disclosure;

FIG. 2B is a schematic illustrating a plane formed along the <100> crystal direction according to one or more embodiments of the disclosure;

FIG. 2C is a schematic illustrating the location of the face of a DRAM slit wall formed along the <100> crystal direction according to one or more embodiments of the disclosure;

FIG. 2D is a schematic illustrating a semiconductor wafer having a notch aligned with the <100> crystal direction according to one or more embodiments;

FIG. 2E is a schematic illustrating a semiconductor wafer having a notch aligned with the <110> crystal direction according to one or more embodiments; and

FIG. 3 illustrates a cross-section schematic representation of a 3D DRAM device formed according to one or more embodiments of the disclosure;

FIG. 4A illustrates a cross-section schematic representation of a 3D DRAM device formed according to one or more embodiments of the disclosure;

FIG. 4B illustrates a cross-section schematic representation of a 3D DRAM device formed according to one or more embodiments of the disclosure and

FIG. 5 is a schematic illustrating a cross-section of a 3D DRAM device in the <100> crystal direction according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

Spatially relative terms, such as “beneath,” “below,” “lower,” “above,” “upper” and the like, may be used herein for ease of description to describe one element's relationship to other element(s) or as illustrated in the Figures. It will be understood that the spatially relative terms are intended to encompass different orientations of a device, such as a semiconductor device, in use or operation in addition to the orientation depicted in the Figures. For example, if the device in the Figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

As used in this specification and the appended claims, the term “substrate” or “wafer” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

The substrate surface may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, vias which have one or more sidewall extending into the substrate to a bottom, and slot vias. The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, or 40:1.

The term “on” indicates that there is direct contact between elements. The term “directly on” indicates that there is direct contact between elements with no intervening elements.

As used in this specification and the appended claims, the terms “precursor,” “reactant,” “reactive gas” and the like are used interchangeably to refer to any gaseous species that can react with the substrate surface.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor. The DRAM device is formed of an array of DRAM cells.

Traditionally, DRAM cells have recessed high work-function metal structures in buried word line structure. In a DRAM device, a bit line is formed in a metal level situated above the substrate, while the word line is formed at the polysilicon gate level at the surface of the substrate. In the buried word line (bWL), a word line is buried below the surface of a semiconductor substrate using a metal as a gate electrode.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great detail to avoid unnecessarily obscuring this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

Although the disclosure will routinely identify specific 3D DRAM devices, and components thereof, it will be readily understood that the device and methods are equally applicable to other memory devices, orientations thereof, as processes for forming such devices. Accordingly, the technology should not be considered to be so limited as for use with these specific devices or methods alone. The disclosure will discuss one possible semiconductor device that may include one or more components, utilizing word line contacts formed on both the top side and bottom side, so that the same number of word line contacts are formed in a reduced word line contact area according to embodiments of the present technology before additional variations and adjustments to this apparatus according to embodiments of the present technology are described.

Semiconductor devices are generally oriented on a semiconductor wafer (or semiconductor substrate) parallel or perpendicular to the preferred crystalline plane of the semiconductor wafer. 3D DRAM devices are generally aligned with respect to a semiconductor wafer such that the slit is parallel to a <110> crystal direction on a semiconductor wafer. The natural cleave direction of a semiconductor wafer is along the preferred crystalline plane, so it is easier to analyze devices for failures and other processing analysis because the devices are easier to cross-section when semiconductor devices are oriented either parallel or perpendicular to the preferred crystalline plane of a semiconductor wafer.

In one or more embodiments, technical advantages are achieved by intentionally rotating substrates at an angle in a range of from greater than 0 degrees up to an optimum near 45 degrees relative to the current <110> crystal direction of the substrate prior to forming devices, e.g., 3D DRAM, thereon, such that now the direction is aligned to the <100> crystal direction. As used herein, the term “<110> crystal direction” refers to a vector perpendicular to the (110) crystal plane. Likewise, the term “<100> crystal direction” refers to a vector perpendicular to the (100) crystal plane.

In one or more embodiments, devices, e.g., 3D DRAM devices, are then fabricated such that they are oriented parallel and perpendicular to the chosen crystalline plane of the semiconductor wafer. In other embodiments, technical advantages are achieved by forming devices, e.g., DRAM, where the device is oriented close to the <100> crystal direction. In standard wafers, the orientation is in the <110> crystal direction, or close to 0 degrees rotation. In one or more embodiments, the angle of rotation may be adjusted between the angles of 10 degrees and 80 degrees. In one or more embodiments, the angle of rotation is in a range of from about 25 degrees to about 65 degrees, or from about 35 degrees to about 55 degrees, or from about 42 degrees to about 48 degrees, with respect to a direction parallel or perpendicular to the cleavage plane of the semiconductor wafer. In one or more embodiments, the angle of rotation is about 40 degrees, or about 41 degrees, or about 42 degrees, or about 43 degrees, or about 45 degrees, or about 46 degrees, or about 47 degrees, or about 48 degrees, or about 49 degrees, or about 50 degrees.

In one or more embodiments, the thickness of the sacrificial layers, e.g., silicon germanium (SiGe) layers, as well as percentage amount, or concentration of, germanium (Ge) may be advantageously reduced by permitting a higher silicon germanium etch rate and a higher selectivity to silicon (Si) for a selective removal process (SRP). In some embodiments, by means of rotating the etch front towards the <100> crystal direction the silicon germanium (SiGe) etch rate may be 2.5 times higher, and, thus, the selectivity to Si becomes 2.5 times greater. In one or more embodiments, the initial wafer or semiconductor substrate advantageously has a rotated crystal orientation. In some embodiments, the initial wafer crystal orientation is rotated in a range of from greater than 0 degrees to 45 degrees from the <110> crystal direction to the <100> crystal direction. In one or more embodiments, when the DRAM device is aligned close to the <100> crystal direction, the lateral etch rate of the DRAM epitaxial film stack advantageously increases by about 2.5 times, while the planar silicon (Si) etch rate (selectivity) is unchanged.

In one or more embodiments, when the DRAM device is oriented to the <100> crystal direction, by virtue of the faster SiGe etch rate, the epitaxial film stack silicon germanium (SiGe) layers may then be reduced in thickness, which reduces stress, which can enable more than twice the total number of Si—SiGe layers to be fabricated compared to an epitaxial film stack when the DRAM device is oriented to the <110> crystal direction due to the ability to have sacrificial silicon germanium (SiGe) layers that are about half the thickness. As the ratio of SiGe thickness to Si thickness decreases, the total stress on the wafer can be higher before crystal relaxation.

In one or more embodiments, rotating the crystal plane to the <100> crystal direction enables a benefit in longer effective channel length for NMOS. This enables a smaller footprint for the NMOS device with similar Ioff performance.

In one or more embodiments, rotating the crystal plane to the <100> crystal direction enhances the epitaxial growth rate for silicon phosphorus (SiP) of bitline and capacitor side source/drain formation. Throughput improvement can be as much as two to three times more for a given SiP thickness grown on <100>.

As used herein, the term “preferred crystalline plane” refers to a crystalline plane orientation generally used in the prior art, such as the cleavage plane of a semiconductor wafer (or semiconductor substrate). In one or more embodiments, a notch may be used as a marker on a semiconductor wafer that indicates the direction of the preferred crystalline plane. Semiconductor wafers are generally manufactured with a marker or notch so that users of lithography equipment can align the semiconductor wafer either parallel or perpendicular to the cleavage plane or crystalline plane direction.

The embodiments of the disclosure are described by way of the Figures, which illustrate devices (e.g., 3D DRAM) and processes for forming semiconductor devices in accordance with one or more embodiments of the disclosure. The processes shown are merely illustrative possible uses for the disclosed processes, and the skilled artisan will recognize that the disclosed processes are not limited to the illustrated applications.

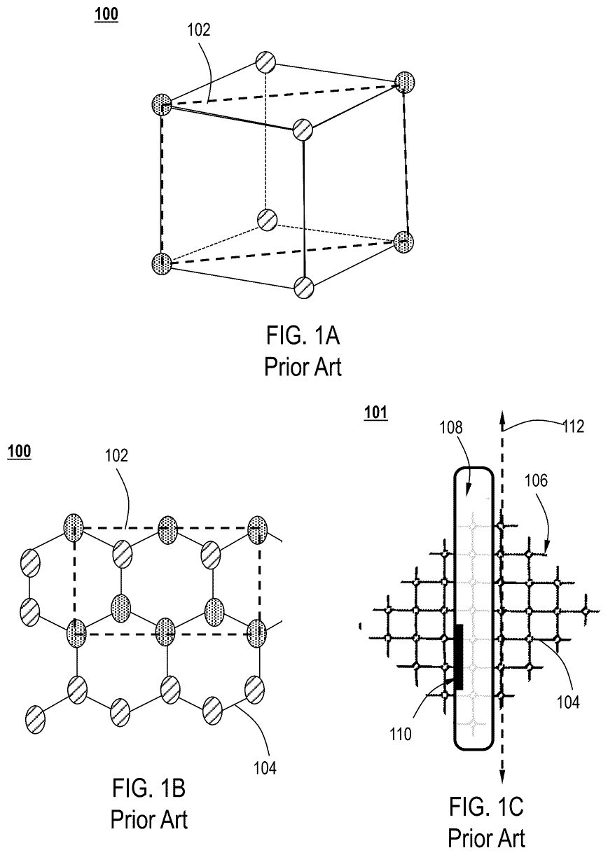

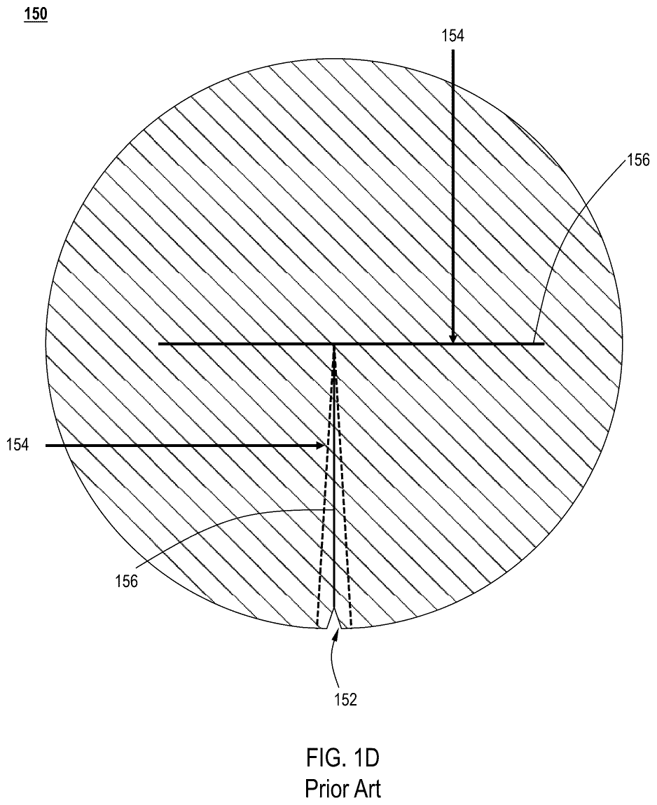

FIGS. 1A to 1C are schematic illustrations showing a crystalline plane orientation according to the prior art. Referring to FIG. 1A, which is according to the prior art, one half of a unit cell 100 is exposed, and a plane 102 formed along the <110> crystal direction is identified. In FIG. 1B, which is according to the prior art, a plane 102 formed along the <110> crystal direction spans across crystals 104 of silicon (Si). With reference to FIG. 1C, which is a top down view of a semiconductor wafer according to the prior art, the DRAM wafer surface 106 shows the orientation of crystals 104 of silicon (Si). When a slit pattern opening 108 is formed in an epitaxial film stack of a 3D DRAM device, the face 110 of the slit pattern opening 108 (i.e., a sidewall of the epitaxial film stack) is parallel to the <110> crystal direction 112. The length of the slit pattern opening 108 is about ten times the width of the slit pattern opening 108.

FIG. 1D is a schematic illustration of a standard semiconductor wafer 150 according to the prior art. The semiconductor wafer 150 has a <110> notch 152 along the <110> crystal direction 154. The (110) crystal face 156 is perpendicular to the <110> crystal direction 154. Typically, the variation in degrees is about ±3 degrees.

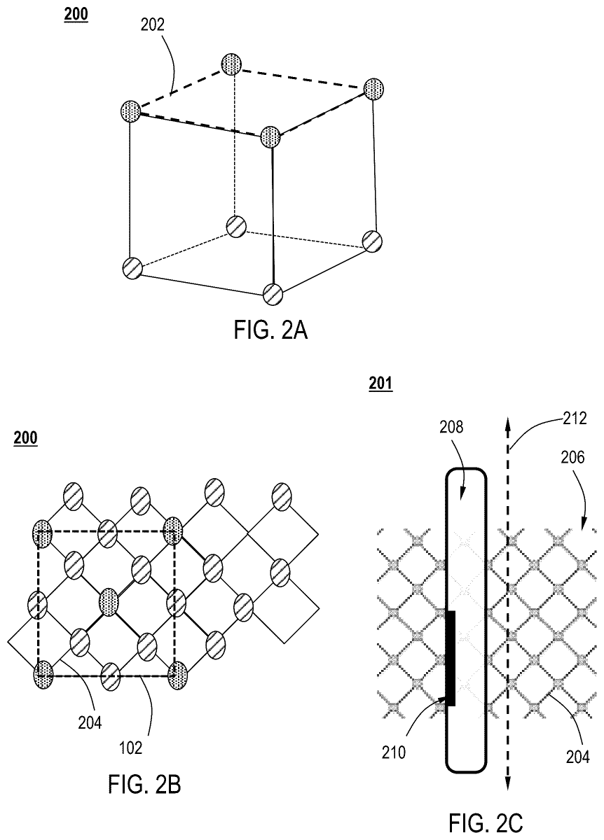

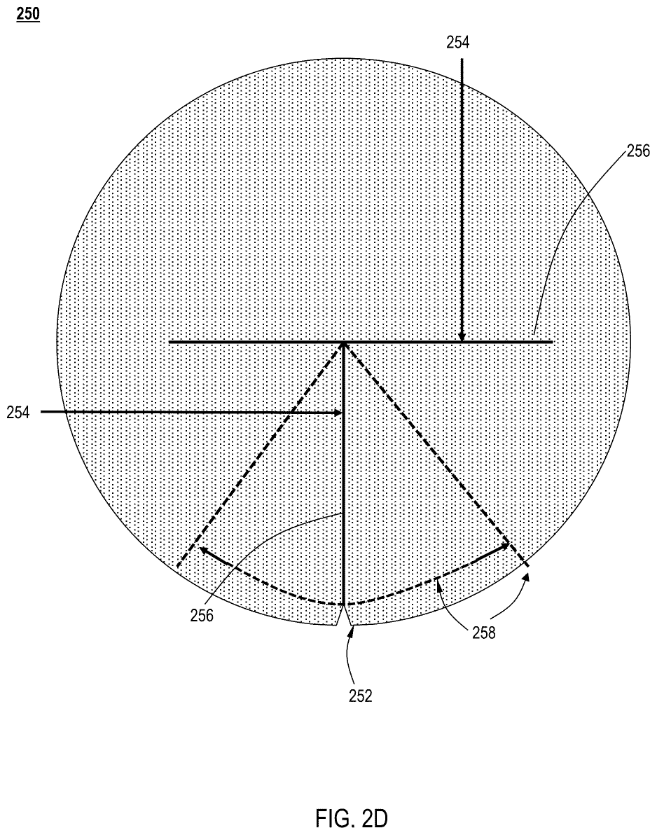

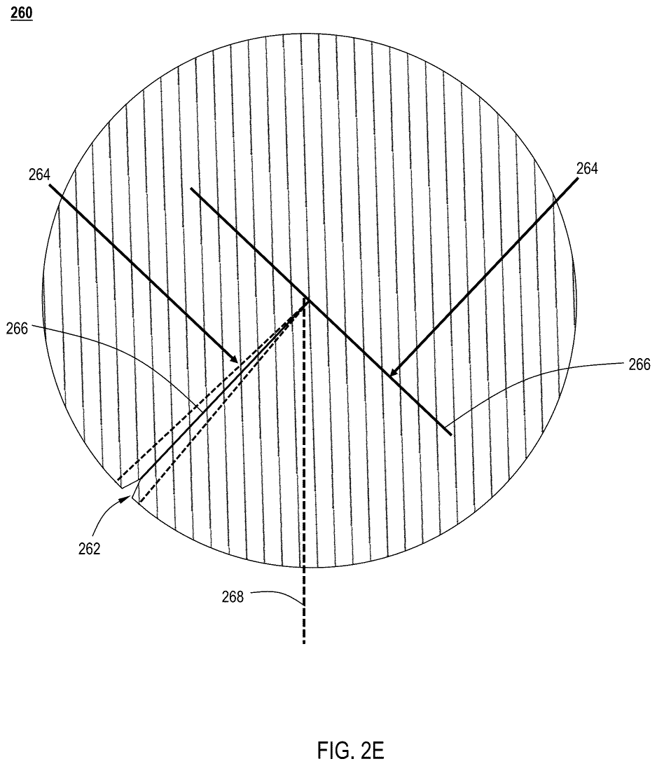

FIGS. 2A to 2C are schematic illustrations showing a crystalline plane orientation according to one or more embodiments of the present disclosure. Referring to FIG. 2A, in one or more embodiments, one half of a unit cell 200 is exposed, and a plane 202 formed along the <100> crystal direction is identified. In FIG. 2B, the plane 202 formed along the <100> crystal direction spans across crystals 204 of silicon (Si). With reference to FIG. 2C, which is a top down view of a semiconductor wafer according to one or more embodiments, the DRAM wafer surface 206 shows the orientation of crystals 204 of silicon (Si). When a slit pattern opening 208 is formed in an epitaxial film stack of a 3D DRAM device, the face 210 of the slit pattern opening 208 (i.e., a sidewall of the epitaxial film stack) is parallel to the <100> crystal direction 212.

FIG. 2D is a schematic illustration of a semiconductor wafer 250 according to one or more embodiments of the disclosure. The semiconductor wafer 250 has a <100> notch 252 along the <100> crystal direction 254. The (100) crystal face 256 is perpendicular to the <100> crystal direction 254. In one or more embodiments, the semiconductor wafer 250 has a notch 252 aligned from zero degrees to 35 degrees (see reference number 258) with respect to the <100> crystal direction. It is noted that aligning the notch 252 at 45 degrees with respect to the <100> crystal direction would put the notch on the <110> crystal direction.

FIG. 2E is a schematic illustration of a semiconductor wafer 260 according to one or more embodiments of the disclosure. The semiconductor wafer 260 has a <110> notch 262 along the <110> crystal direction 264. The (110) crystal face 266 is perpendicular to the <110> crystal direction 264. Typically, the variation in degrees is about +3 degrees. In one or more embodiments, prior to patterning the horizontal or vertical slit pattern opening 208, the semiconductor wafer 260 is rotated in a range of from 10 degrees to 45 degrees. Thus, the slit pattern opening 208 is then formed on the <100> crystal direction.

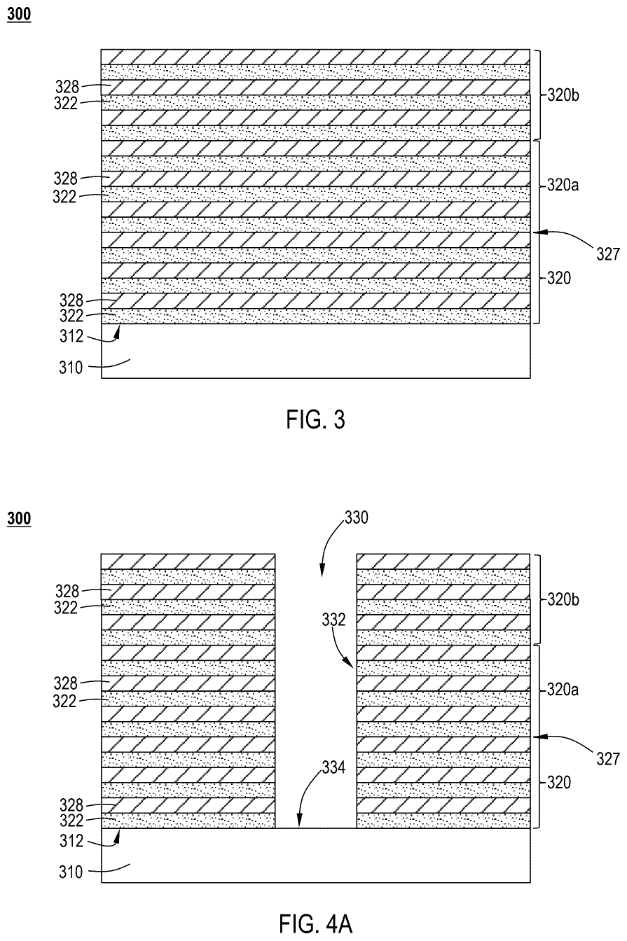

FIG. 3 illustrates a cross-section schematic representation of a 3D DRAM device formed according to one or more embodiments of the disclosure. In one or more embodiments, a plurality of film stacks 320 are formed on a substrate 310 having a substrate surface 312.

The embodiment illustrated in FIG. 3 shows three film stacks 320 (including films stacks 320a, 320b). The skilled artisan will recognize that this is merely representative and that there can be more or less film stacks 320. In some embodiments, there are greater than 50, 100, 150, or 200 film stacks 120.

In one or more embodiments, the film stacks 320 are epitaxial film stacks that comprise a plurality of alternating layers of a first material layer and a second material layer. In some embodiments, the first material layer comprises a silicon channel layer 322, and the second material layer comprises a sacrificial layer 328.

At least some of the film stacks 320, or each of the film stacks 320, comprises a silicon channel layer 322 and a sacrificial layer 328. The skilled artisan will recognize that the silicon channel layer 322 in the first stack 320a is formed on the substrate surface 312, or directly on the substrate surface 312. The silicon channel layers 322 of subsequent film stacks 320a are formed on the surface 327 of the sacrificial layer 328 of the previous film stack 320.

In one or more embodiments, the silicon channel layer 322 has a thickness in a range of from greater than 2 nm to 80 nm, including in a range of from greater than 2 nm to 75 nm, including about 5 nm, about 10 nm, about 15 nm, about 25 nm, about 35 nm, about 45 nm, about 55 nm, about 60 nm, about 65 nm, about 70 nm, about 75 nm and about 80 nm. In one or more embodiments, the silicon channel layer 322 comprises, consists essentially of, or consists of completely of, epitaxial silicon. The epitaxial silicon is completely or mostly single crystal.

In one or more embodiments, a sacrificial layer 328 is formed on, or directly on the silicon channel layer 322. In one or more embodiments, the sacrificial layer 328 comprises a silicon germanium (SiGe) layer. The sacrificial layer 328 may be doped with a dopant or may be undoped. The dopant may comprise any suitable dopant. In some embodiments, the dopant comprises a Group III-V element. In some embodiments, the dopant comprises one or more of carbon (C), boron (B), nitrogen (N), phosphorus (P), or oxygen (O). In some embodiments, the dopant comprises one or more of carbon (C) or boron (B).

In one or more embodiments, the sacrificial layer 328 comprises a silicon germanium (SiGe) layer having a germanium concentration or germanium content in a range of from greater than 0 atomic % to 30 atomic % germanium, including in a range of from greater than 0 atomic % to 25 atomic % germanium, including in a range of from greater than 0 atomic % to 25 atomic % germanium, including in a range of from greater than 0 atomic % to 15 atomic % germanium, including in a range of from 5 atomic % to 15 atomic %, including in a range of from 10 atomic % to 30 atomic % germanium, and including in a range of from 10 atomic % to 25 atomic % germanium. In one or more embodiments, the sacrificial layer 328 comprises a silicon germanium (SiGe) layer having a germanium content of greater than 0 atomic %, including about 1 atomic %, about 2 atomic %, about 3 atomic %, about 4 atomic %, about 5 atomic %, about 6 atomic %, about 7 atomic %, about 8 atomic %, about 9 atomic %, about 10 atomic %, about 11 atomic %, about 12 atomic %, about 13 atomic %, about 14 atomic %, about 15 atomic %, about 16 atomic %, about 17 atomic %, about 18 atomic %, about 19 atomic %, about 20 atomic %, about 21 atomic %, about 22 atomic %, about 23 atomic %, about 24 atomic %, about 25 atomic %, about 26 atomic %, about 27 atomic %, about 28 atomic %, about 29 atomic %, or about 30 atomic %.

The various layers described can be formed by any suitable technique known to the skilled artisan. For example, one or more of the films can be formed by epitaxial growth, chemical vapor deposition, atomic layer deposition, physical vapor deposition, ion implantation, etc. In some embodiments, each of the silicon channel layer 322 and the sacrificial layer 328 are epitaxially grown. In some embodiments, each of the silicon channel layer 322 and the sacrificial layer 328 are independently grown at a temperature in the range of 500° C. to 800° C.

In one or more embodiments, the stress of the film stack 320 is modulated by making the SiGe layers thinner with respect to the Si layers. This is enabled by intentionally rotating the semiconductor wafer at an angle in a range of from greater than 0 degrees to 45 degrees relative to the <110> crystal direction of the semiconductor wafer prior to forming the film stacks 320. In some embodiments, the notch alignment of the semiconductor wafer is rotated in a range of from greater than 0 degrees to 45 degrees toward the <100> crystal direction, or in a range of from greater than 10 degrees to 45 degrees toward the <100> crystal direction. In other embodiments, the film stacks 320 are fabricated such that they are oriented between 0 and 45 degrees from a direction parallel or perpendicular to the <110> crystal direction of the semiconductor wafer.

In other embodiments, film stacks 320 are oriented along a plane that is aligned from greater than 0 degrees to 45 degrees to the <110> crystal direction. In one or more embodiments, the angle of rotation may be adjusted between the angles of 10 degrees and 80 degrees. In one or more embodiments, the angle of rotation is in a range of from about 25 degrees to about 65 degrees, or from about 35 degrees to about 55 degrees, or from about 40 degrees to about 50 degrees, or from about 42 degrees to about 48 degrees, with respect to a direction parallel or perpendicular to the current <110> plane of the semiconductor wafer. In one or more embodiments, the angle of rotation is about 40 degrees, or about 41 degrees, or about 42 degrees, or about 43 degrees, or about 45 degrees, or about 46 degrees, or about 47 degrees, or about 48 degrees, or about 49 degrees, or about 50 degrees.

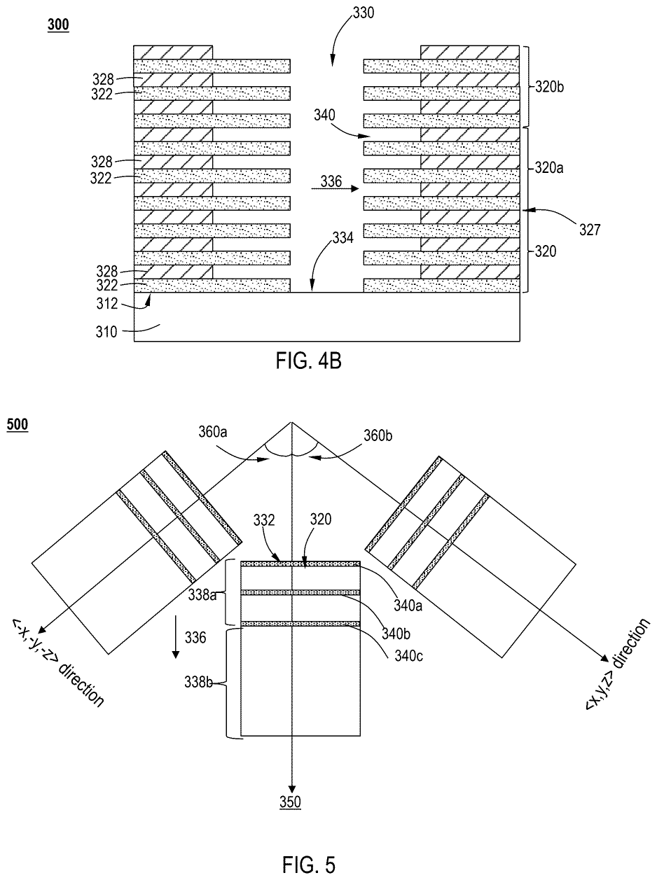

FIGS. 4A and 4B illustrate the 3D DRAM device 100 of FIG. 3. In some embodiments of the method, an opening 330, e.g., a slit pattern opening, through all of the film stacks 320 to the substrate surface 312 (or a distance into the substrate 310) is patterned. The skilled artisan will understand how to form the opening 330 using lithography. As illustrated in FIG. 4A, the opening 330 has at least one sidewall 332 and a bottom surface 334. In one or more embodiments, the slit pattern opening 330 has an elongated direction and a shortened direction. In some embodiments, the elongated direction is aligned within 5 degrees of the <100> crystal direction.

As illustrated in FIG. 4B, after formation of the opening 330 in the film stacks 320, one or more sacrificial layer 328 may be completely or partially selectively etched, laterally, from the film stacks 320 through the opening 330. In one or more embodiments, before laterally etching the epitaxial film stack 320 through the slit pattern opening 330 top form opening 340 between the alternating silicon channel layers 322, the semiconductor wafer has a wafer bow of magnitude from 200 μm to 450 μm without strain relaxation, with wafer bow reducing with lateral etching of the SiGe layers.

FIG. 5 illustrates a cross-section view of a 3D DRAM device 500 with an etched film stack 320 according to the method of one or more embodiments. In one or more embodiments, the sidewall 332 of the epitaxial film stack 320 of the DRAM device is selectively etched along crystal planes 340a, 340b, 340c that are parallel to the <100> crystal direction 350. In one or more embodiments, selective removal processes, such as selective lateral etching, occur in the <100> crystal direction. In one or more embodiments, the selective removal process may comprise any suitable removal process known to the skilled artisan. In one or more embodiments, laterally etching the epitaxial film stack 320 comprises one or more of a wet etch process or a dry etch process.

In one or more embodiments, a first portion 338a of the epitaxial film stacks 320 is laterally etched away along a lateral etching direction 336, while a second portion 338b remains. In one or more embodiments, etching is done through crystal planes 340a, 340b, 340c parallel to one another until the desired recess depth is achieved. When the opening 330 is formed in the epitaxial film stacks 320 of the 3D DRAM device, the sidewall 332 of the opening 330 is aligned to the <100> crystal direction. In one or more embodiments, the lateral etching occurs along a direction with an angle 360a, 360b between greater than 0 degrees to optimal it is close to 45 degrees, which is then aligned to the <100> crystal direction 350. In one or more embodiments, this angle is in a range of from about 10 degrees to about 45 degrees, or from about 25 degrees to about 45 degrees, or from about 35 degrees to about 45 degrees, or from about 40 degrees to about 45 degrees, or from about 42 degrees to about 45 degrees.

In one or more embodiments, metal deposition and other processes can be carried out in an isolated environment (e.g., a cluster process tool). Accordingly, some embodiments of the disclosure provide integrated tool systems with related process modules to implement the methods.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of etching a semiconductor structure, the method comprising:
etching a slit through an epitaxial film stack formed on a semiconductor wafer to expose a sidewall of the epitaxial film stack, the sidewall oriented along a plane of the epitaxial film stack that is aligned from 0 degrees to 35 degrees to a <100> crystal direction of the epitaxial film stack.

2. The method of claim 1, wherein the slit has an elongated direction and a shortened direction, the elongated direction aligned from 0 degrees to 35 degrees to the <100> crystal direction.

3. The method of claim 1, wherein the epitaxial film stack comprises a plurality of alternating layers of a first material layer and a second material layer.

4. The method of claim 3, further comprising laterally etching the sidewall of the epitaxial film stack.

5. The method of claim 4, wherein the first material layer comprises silicon (Si) and the second material layer comprises silicon germanium (SiGe).

6. The method of claim 4, wherein laterally etching the epitaxial film stack comprises at least partially removing the second material layer.

7. The method of claim 6, wherein laterally etching the epitaxial film stack comprises completely removing the second material layer.

8. The method of claim 4, wherein laterally etching the epitaxial film stack comprises one or more of a wet etch process or a dry etch process.

9. The method of claim 1, wherein the sidewall is aligned in a range of from 0 degrees to 10 degrees to the <100> crystal direction.

10. The method of claim 1, wherein the sidewall is aligned 0 degrees to the <100> crystal direction.

11. The method of claim 3, wherein the second material layer comprises in a range of from >0 atomic % germanium to 20 atomic % germanium.

12. The method of claim 3, wherein the second material layer comprises in a range of from >10 atomic % germanium to 15 atomic % germanium.

13. The method of claim 1, wherein the semiconductor structure is a 3D DRAM device structure.

14. The method of claim 4, wherein, before laterally etching, the semiconductor wafer has a wafer bow in a range of from 200 μm to 450 μm without strain relaxation and wafer bow decreases with lateral etching of the second material layer.

15. The method of claim 4, wherein the lateral etch rate is in a range of from 0.5 nm/see to 5 nm/sec.

16. The method of claim 1, wherein the semiconductor wafer has a notch aligned from zero degrees to 35 degrees with respect to the <100> crystal direction.

17. The method of claim 1, wherein the semiconductor wafer has a notch aligned with a <110> crystal direction, and, prior to etching the slit, the semiconductor wafer is rotated in a range of from 10 degrees to 45 degrees.

18. A method of etching a semiconductor structure, the method comprising:
forming an epitaxial film stack on the semiconductor wafer; and
etching a slit through the epitaxial film stack to expose a sidewall of the epitaxial film stack, the sidewall oriented along a plane of the epitaxial film stack that is aligned from 10 degrees to 35 degrees to a <100> crystal direction.

19. The method of claim 18, wherein the semiconductor wafer has a notch aligned from zero degrees to 35 degrees toward the <100> crystal direction.

20. The method of claim 18, wherein the semiconductor wafer has a notch aligned with a <110> crystal direction, and, prior to etching the slit, the semiconductor wafer is rotated from 10 degrees to 35 degrees.

21. The method of claim 18, the semiconductor wafer has a notch aligned with a <110> crystal direction, and, prior to etching the slit, the epitaxial film stack is rotated from 10 degrees to 35 degrees.

22. The method of claim 18, wherein the slit has an elongated direction and a shortened direction, the elongated direction aligned from 10 degrees to 35 degrees to the <100> crystal direction.
